(19) United States
(12) Patent Application Publication
(10) Pub. No.: US 2014/0041186 A1
(43) Pub. Date: Feb. 13, 2014

(54) METHOD FOR LOADING AND UNLOADING A CASSETTE

(71) Applicants: Michael Schilp, Regensburg (DE); Adolf Zitzmann, Teunz (DE); Josef Zimmermann, Regensburg (DE)

(72) Inventors: Michael Schilp, Regensburg (DE); Adolf Zitzmann, Teunz (DE); Josef Zimmermann, Regensburg (DE)

(73) Assignee: Zimmermann & Schilp Handhabungstechnik GmbH, 93055 Regensburg (DE)

(21) Appl. No.: 13/884,779

(22) PCT Filed: Nov. 11, 2011
(86) PCT No.: PCT/DE2011/001977

§ 371 Date: Oct. 29, 2013

(30) Foreign Application Priority Data
Nov. 11, 2010 (DE) 10 2010 050 918.3

(51) Int. Cl. C23C 16/458; B05B 5/08

(52) U.S. Cl. CPC C23C 16/458; B05B 5/082
USPC 29/426.1

(57) ABSTRACT

The present invention relates to a method for loading and unloading a cassette which is used, for example, in plasma coating processes, wherein the following method steps are carried out: a. providing a cassette (1) which can be assembled and disassembled using a disassembly and assembly robot, b. automatic disassembling of the cassette such that the bottoms (2) of the cassette are separated from one another, c. transferring and associating the bottoms (2) to at least one automatic feeding apparatus which populates the bottoms (2) with workpieces to be processed, d. mounting the populated bottoms (2) to the cassette (1), e. transferring the cassette (1) to the process site where the process should be executed, f. executing the process, g. transferring the cassette (1) to the disassembly and assembly robot or to a further disassembly and assembly robot, h. disassembling the cassette in such a way that the bottoms (2) of the cassette are separated from one another, and i. automatic removal of the workpieces being processed.

The present invention relates to a method for loading and unloading a cassette which, e.g., is used in plasma coating processes.

Such a cassette has a plurality of spaced-apart carrier plates. Flat workpieces to be processed, such as e.g. wafers, are placed in the spaces between the carrier plates and removed again after processing. Multiple grippers are known, e.g., from the semiconductor technology, for these operating steps and capable of introducing a stack of these workpieces in spaced-apart relationship and into the cassette at the same time and of removing them again. These multiple grippers are, however, primarily suitable to deposit the workpieces into the narrow compartments of the cassette or to remove them again.

In some cases however, the workpieces have to be secured in the compartments of the cassette. This securement may, e.g., be required, when the populated cassette is subsequently moved by a robot in different directions and the workpieces would fall out without a securement.

Securement is further necessary, e.g. in plasma coatings. For this purpose, it is necessary to provide the workpieces with a reliable electrical contact to a voltage source. This can be realized, e.g. by moving the rectangular wafer with a vacuum gripper into the compartment and then rotating it, so that the corners of the wafer are pressed under holding and contact pins to thereby establish both a mechanical securement and an electrical contact. The removal of the wafer is implemented in the same manner, i.e. the gripper moves into the compartment, draws the wafer to it, and rotates it in such a way that it can be extracted without colliding with the holding and contact pins.

This technology is disadvantageous because the required gripper systems are relatively complex and thus expensive or because incorrect loading is oftentimes encountered, when the grippers lack precision and reliability so that a relatively high proportion of wafer breakage is experienced. The gripper systems have the further drawback that they are not available for different sizes of the cassettes and therefore have to be custom-made. As a result, overall costs of such a process increase.

It is therefore the object of the invention to provide a loading and unloading method for a cassette, in which the workpieces can be supplied quickly and safely with a high reliability and also removed again in a same manner. Furthermore, the method should require an inexpensive device technology.

This object of the invention is achieved by a loading and unloading method for a cassette, having the following method steps:
a. providing a cassette which can be assembled and disassembled using a disassembly and assembly robot, with a disassembly and assembly robot to be understood to relate to any type of fully automated automatically operating device.
b. automatic disassembling of the cassette such that the bottoms of the cassette are separated from one another,
c. transferring and associating the bottoms to at least one automatic feeding apparatus which populates the bottoms with workpieces to be processed,
d. mounting the populated bottoms to the cassette,
e. transferring the cassette to the process site where the process should be executed,
f. executing the process,
g. transferring the cassette to the disassembly and assembly robot or to a further disassembly and assembly robot,
h. disassembling the cassette in such a way that the bottoms of the cassette are separated from one another, and
i. automatic removal of the workpieces being processed.

The skilled artisan will appreciate that the bottoms can be populated again with workpieces. There is no need for further explanation that the various bottoms can be populated at several feed stations. The skilled artisan is also familiar as to how a multiplicity of bottoms can be joined together again to a cassette 1 using a robot.

As a result of this surprising change of paradigm in the feed technology, it is possible to carry out a very rapid, reliable and precise loading with relatively little technological effort, since the workpieces do not have to be laterally threaded into narrow slots or compartments, but fitted from above upon the individual bottoms 2 and secured if necessary in a relatively uncomplicated manner. The advantage of the method according to the invention becomes especially clear when it is necessary to secure a first workpiece in each of the narrow compartments of the cassette and parallel thereto a second workpiece upon the topside of the compartment. The method according to the invention requires only a turning of the bottom 2 so that the backside can also be populated with workpieces. In this case, devices are provided for securing the workpiece upon the bottom 2 so that the workpieces placed on one side cannot drop, when the bottom is turned.

According to claim 2, the cassette is provided for a plasma coating process. It should be noted that because of the complex handling of very thin workpieces, the method is especially suitable for a plasma coating process.

According to claim 3, the cassette is provided for an electrostatic coating process.

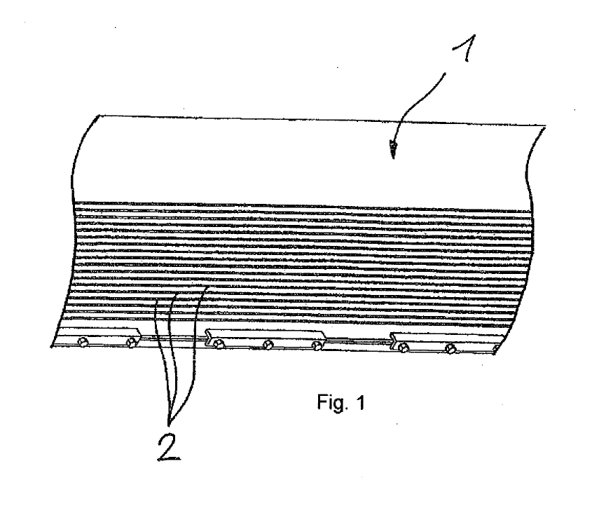

FIG. 1 shows a section of a cassette 1 having a plurality of bottoms .2. As can be seen, introduction and removal of workpieces, using the conventional technology is difficult.

1-3. (canceled)

4. A method for loading and unloading a cassette, comprising:
automatically disassembling a cassette by separating bottoms of the cassette from one another;
transferring the bottoms to at least one automatic feeding apparatus to populate the bottoms with workpieces to be processed;
mounting the populated bottoms to the cassette;
transferring the cassette to a process site for undergoing a process;
transferring the cassette, after undergoing the process, to a disassembly and assembly robot, for disassembling the cassette to separate the bottoms; and
automatically removing the workpieces being processed.

5. The method of claim 1, wherein the cassette is provided for a plasma coating process.

6. The method of claim 1, wherein the cassette is provided for an electrostatic coating process.
